(19) United States
(12) Patent Application Publication
(10) Pub. No.: US 2026/0043143 A1
(43) Pub. Date: Feb. 12, 2026

(54) NOBLE GAS PLASMA CURES TO ENABLE INCREASED CROSSLINKING IN LOW-K DIELECTRIC FILMS

(71) Applicant: Applied Materials, Inc., Santa Clara, CA (US)

(72) Inventors: Purvam MODI, Sunnyvale, CA (US); Erik JOHNSON, Santa Clara, CA (US); Bhargav S. CITLA, Fremont, CA (US); Srinivas D. NEMANI, Sunnyvale, CA (US); Ellie Y. YIEH, San Jose, CA (US)

(21) Appl. No.: 18/909,425

(22) Filed: Oct. 8, 2024

Related U.S. Application Data
(60) Provisional application No. 63/680,009, filed on Aug. 6, 2024.

(51) Int. Cl. C23C 16/56; C23C 16/34; C23C 16/40; C23C 16/458; C23C 16/505

(52) U.S. Cl. CPC C23C 16/56; C23C 16/458; C23C 16/505; C23C 16/345; C23C 16/401

(57) ABSTRACT

Embodiments of the present disclosure generally relate to methods of plasma curing a dielectric material layer formed on a substrate. More specifically, the methods disclosed herein utilize a xenon (Xe) containing gas to generate a plasma that allows for greater dielectric compositional modulation. In some embodiments, a method of curing a substrate includes depositing a dielectric film onto a substrate to form a dielectric layer on a surface of a substrate, and performing a plasma cure operation on the formed dielectric layer. The plasma cure operation includes generating a plasma over a surface of the formed dielectric layer by delivering a RF power to a plasma process gas. The plasma process gas include Xe and H₂.

### BACKGROUND

### Field

Embodiments of the present disclosure generally relate to methods of plasma curing a dielectric material layer formed on a substrate. More specifically, the methods disclosed herein utilize a noble gas containing process gas to generate a plasma that allows for greater dielectric compositional modulation.

### Description of the Related Art

Advancements in semiconductor fabrication have continually lead to smaller device dimensions of integrated circuit components, and thus smaller gaps between the components. However, the reduction in size brings along new challenges pertaining to device fabrication. For instance, the widths of trenches on modern devices have been narrowed to a point where the aspect ratio of trench depth to width becomes high enough to result in challenges with filling the trench with a dielectric material. In response, flowable chemical vapor deposition (FCVD) has been developed to address such fabrication challenges.

While the development of FCVD processes highlight advancements in the field of device fabrication, the lack of suitable post-deposition processes brings forth another challenge. Dielectric materials formed using FCVD deposition methods may be unstable and/or may contain reactive species that react with air. Traditional/conventional post-treatment methods (e.g., ultraviolet (UV) exposure and thermal annealing) for films formed via a FCVD process have been found to be deficient in maintaining the overall stability and quality of the dielectric film and adjacently formed layers and structures. In response, plasma curing methods have been investigated as a viable post-deposition treatment to prevent or reduce the quality and stability issues found in convention FCVD process sequences. However, previous plasma curing methods have suffered from a lack of cure depth, undesirable film densities, and poor electrical isolation characteristics.

Thus, there is a need to develop new cure methods to maintain and improve the overall stability and quality of dielectric films.

### SUMMARY

Embodiments of the present disclosure generally relate to methods of plasma curing a dielectric material layer formed on a substrate. More specifically, the methods disclosed herein utilize a noble gas containing process gas, such as a xenon (Xe) containing gas, to generate a plasma that allows for greater dielectric compositional modulation.

In some embodiments, a method of curing a substrate includes depositing a dielectric film onto a substrate to form a dielectric layer on a surface of a substrate, and performing a plasma cure operation on the formed dielectric layer. The plasma cure operation includes generating a plasma over a surface of the formed dielectric layer by delivering a RF power to a plasma process gas. The plasma process gas includes a noble gas (e.g., Xe) and H₂.

In some embodiments, a method of curing a substrate includes positioning a substrate onto a substrate support within a processing chamber. The substrate includes an uncured dielectric material disposed thereon. The method further includes performing a plasma cure operation on the substrate. The plasma cure operation includes generating a plasma over a surface of a dielectric layer by delivering a RF power supplied from a first RF source to a plasma process gas. The plasma process gas includes Xe and H₂ at a ratio of about 0.1:1 to about 1:0.1. The plasma cure operation also includes applying a RF bias to the substrate support. The RF bias is provided from a second RF source.

In some embodiments, a method of forming a cured substrate includes positioning a substrate onto a substrate support within a processing chamber. The substrate includes an uncured dielectric material disposed thereon. The method further includes performing a plasma cure operation on the substrate to form a cured substrate. The plasma cure operation includes introducing a plasma process gas having Xe and H₂ to the processing chamber. The plasma cure operation further includes applying an RF power to the plasma process gas to generate a plasma within the plasma processing chamber. The cured dielectric material formed on the substrate has a cure depth of about 600 Å to about 1000 Å.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts an apparatus utilized to perform a deposition process, according to an embodiment.

FIG. 2 depicts a top plan view of a processing tool, according to an embodiment.

FIG. 3 is a process flow diagram illustrating a method of plasma curing a dielectric material, according to an embodiment.

FIG. 4 is a Fourier Transform Infrared (FTIR) spectra showing the compositional signals of a processed substrate, according to an embodiment.

FIG. 5 is a Fourier Transform Infrared (FTIR) spectra showing the compositional signals of a processed substrate, according to an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present disclosure includes the use of plasma cure processes on a formed flowable chemical vapor deposition (FCVD) film used to form a dielectric layer on a surface of a substrate. The plasma cure processes disclosed herein incorporate the use of a noble gas based plasma gas to promote curing of the dielectric material layer. Substrates produced from the plasma cure processes described herein, which incorporate the use of a noble gas based plasma exhibit improved electrical properties over substrates cured using traditional/conventional cure processes. Such electrical property improvements can be attributed to compositional, density, and chemical bonding changes within the material disposed within the formed FCVD layer. Such compositional and density changes are indicative of increased crosslinking of the dielectric material layer.

Methods and apparatus for curing a substrate and/or forming an interconnect device are provided herein. In some embodiments, a method for forming an integrated circuit structure includes: contacting a dielectric material containing layer with a plasma under conditions suitable for curing the dielectric material. The methods and apparatus of the present disclosure advantageously stabilize or improve dielectric material containing layer such as dielectric materials formed or deposited by FCVD methods. In some embodiments, methods and apparatus of the present disclosure form variants of deposited dielectric material such as by curing the dielectric material using a plasma, such as a noble gas containing plasma, such as a Xe containing plasma, to alter the physical and compositional make-up of the cured dielectric material. For example, in some embodiments, a silicon nitride dielectric containing material may be deposited having reactive hydrogen incorporated into the silicon nitride material. Unless cured, hydrogen may problematically react with air and moisture therein to form an oxynitride layer of dielectric material, such as silicon oxynitride (SiOₓN_{y}). In some embodiments, curing in accordance with the present disclosure reduces the atomic oxygen percentage within the cured dielectric material and increases the atomic nitrogen percentage within the cured dielectric material. In some embodiments where, for example, a dielectric material formed by a FCVD process is silicon nitride with hydrogen incorporated therein, the process of curing the deposited dielectric material in accordance with the present disclosure reduces unstable material formation such as SiOₓN_{y}, wherein a ratio of x to y is greater than 1.

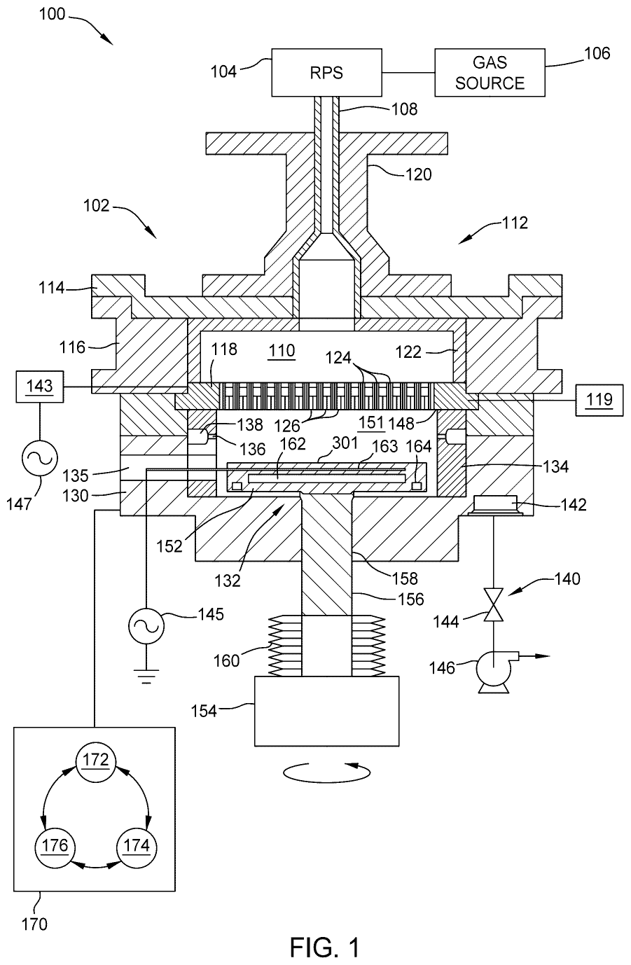

Accordingly, the present disclosure includes depositing a dielectric material in a feature, such as a trench that has a high aspect ratio, that provides a good gap-filling capability within the deep trench formed on the substrate. FIG. 1 is a cross-sectional view of a deposition chamber 100 for performing a deposition process that can deposit a dielectric material for semiconductor applications in accordance with the present disclosure. Non-limiting suitable processing chambers that may be adapted for use herein include, for example, an HDP-PRODUCER® or C3® processing chamber available from Applied Materials, Inc. of Santa Clara, Calif. Other process chambers, including ones available from other manufacturers, may also be suitably used in connection with the teachings provided herein.

Referring to FIG. 1, in embodiments the deposition processing chamber 100 includes a processing chamber body 102 and a remote plasma source 104 coupled to the processing chamber body 102. The remote plasma source 104 may be any suitable source that is capable of generating radicals. The remote plasma source 104 may be any suitable remote plasma source, such as a radio frequency (RF) or very high radio frequency (VHRF) capacitively coupled plasma (CCP) source, an inductively coupled plasma (ICP) source, a microwave induced (MW) plasma source, an electron cyclotron resonance (ECR) chamber, or a high density plasma (HDP) chamber. The remote plasma source 104 may include one or more gas sources 106, and may be coupled to the deposition chamber 100 by a radical conduit 108. One or more process gases, which may be radical-forming gases, may enter the remote plasma source 104 via the one or more gas sources 106. In some embodiments, the one or more process gases may include a chlorine-containing gas, a fluorine containing gas, an inert gas, an oxygen-containing gas, a nitrogen-containing gas, a hydrogen containing gas, or any combination thereof. Radicals generated in the remote plasma source 104 travel into the deposition chamber 100 through the radical conduit 108 coupling to the deposition chamber 100, reaching an interior processing region 151 defined in the deposition chamber 100.

The radical conduit 108 is a part of a lid assembly 112, which also includes a radical cavity 110, a top plate 114, a lid rim 116, and a showerhead 118. The radical conduit 108 may include a material that is substantially nonreactive to radicals, such as aluminum nitride (AlN), silicon dioxide (SiO₂), yttrium oxide (Y₂O₃), magnesium oxide (MgO), anodized aluminum oxide (Al₂O₃), an oxide mineral (e.g., sapphire), ceramics containing one or more of aluminum oxide (Al₂O₃), an oxide mineral (e.g., sapphire), aluminum nitride (AlN), yttrium oxide (Y₂O₃), magnesium oxide (MgO), or a plastic material. A representative example of a suitable silicon dioxide (SiO₂) material is quartz. The radical conduit 108 may be disposed within and supported by a radical conduit support member 120. The radical conduit support member 120 may be disposed on the top plate 114, which rests on the lid rim 116.

In some embodiments, the radical cavity 110 is positioned below and coupled to the radical conduit 108, and the radicals generated in the remote plasma source 104 travel to the radical cavity 110 through the radical conduit 108. In some embodiments, the radical cavity 110 includes the top plate 114, the lid rim 116, and the showerhead 118. Optionally, the radical cavity 110 may include a liner 122. The liner 122 may cover surfaces of the top plate 114 and the lid rim 116 that are exposed to the radical cavity 110. In at least one embodiment, radicals from the remote plasma source 104 pass through a plurality of tubes 124 disposed in the showerhead 118 to enter into an interior processing region 151. The showerhead 118 further includes a plurality of openings 126 that are smaller in diameter than the plurality of tubes 124. The plurality of openings 126 are connected to an internal volume (not shown) that is not in fluid communication with the plurality of tubes 124. One or more fluid sources 119 may be coupled to the showerhead 118 for introducing a fluid mixture into an interior processing region 151 of the deposition chamber 100. The fluid mixture may include a precursor, and/or other carrier fluids. The fluid mixture may be a mixture of gases and liquids.

The deposition chamber 100 may include the lid assembly 112, a chamber body 130 and a substrate support assembly 132. The substrate support assembly 132 may be at least partially disposed within the chamber body 130. The chamber body 130 may include a slit valve 135 to provide access to the interior of the deposition chamber 100. The chamber body 130 may include a liner 134 that covers the interior surfaces of the chamber body 130. The liner 134 may include one or more apertures 136 and a pumping channel 138 formed therein that is in fluid communication with a vacuum system 140. The apertures 136 can provide a flow path for gases into the pumping channel 138, which provides an egress for the gases within the deposition chamber 100.

The vacuum system 140 may include a vacuum port 142, a valve 144, and a vacuum pump 146. The vacuum pump 146 may be in fluid communication with the pumping channel 138 via the vacuum port 142. The apertures 136 allow the pumping channel 138 to be in fluid communication with the interior processing region 151 within the chamber body 130. The interior processing region 151 includes a lower surface 148 of the showerhead 118 and an upper surface 150 of the substrate support assembly 132, and the interior processing region 151 is surrounded by the liner 134.

The substrate support assembly 132 may include a substrate support member 152 to support a substrate within the chamber body 130. The substrate may be any standard wafer size, such as about 200 mm to about 450 mm in diameter. The substrate support member 152 may include a material composition having aluminum nitride (AlN) or aluminum, depending on operating temperature. The substrate support member 152 may be configured to chuck the substrate to the substrate support assembly 122.

The substrate support member 152 may be coupled to a lift mechanism 154 via a shaft 156 extending through a centrally-located opening 158 formed in a bottom surface of the chamber body 130. The lift mechanism 154 may be flexibly sealed to the chamber body 130 by one or more bellows 160, which prevent vacuum leakage from around the shaft 156. The lift mechanism 154 allows the substrate support member 152 to be moved vertically within the chamber body 130 between a process position and a transfer position. In at least one embodiment, the transfer position is slightly below the opening of the slit valve 135. During operation, the spacing between the substrate 301 and the showerhead 118 may be minimized in order to maximize radical flux at the substrate surface. For example, the spacing may be between about 100 mm and about 5,000 mm. The lift mechanism 154 may be capable of rotating the shaft 156, which in turn rotates the substrate support member 152, allowing for the substrate disposed on the substrate support member 152 to be rotated during operation.

One or more heating elements 162 and a cooling channel 164 may be embedded in the substrate support member 152. The heating elements 162 and cooling channel 164 may be used to control the temperature of the substrate during operation. The heating elements 162 may include any suitable heating elements, such as one or more resistive heating elements. The heating elements 162 may be connected to one or more power sources (not shown). The heating elements 162 may be controlled individually to have independent heating and/or cooling control on multi-zone heating or cooling. With the ability to have independent control on multi-zone heating and cooling, the substrate temperature profile can be enhanced at any giving process conditions. In some embodiments, a coolant may be flown flow through the cooling channel 164 to cool the substrate. The substrate support member 152 may also include one or more gas passages extending to the upper surface 150 for flowing the cooling gas to the backside of the substrate.

A RF power source 147 may be coupled to the showerhead 118 through a RF power source matching box 143. The RF power source 147 may be low frequency, high frequency, or very high frequency. In one example, the RF power source 147 is configured to deliver an RF signal to the showerhead 118 at a frequency between 100 kHz and 120 MHz, such as between 2 MHz and 60 MHz. In some embodiments, the RF power source 147 is a high frequency RF generator that may generate high density plasma for deposit high density film layers. In one example, the RF power source 147 may serve as a capacitively coupled RF energy transmitting device that can generate and control the capacitively coupled plasma (CCP) generated in the interior processing region 351 above the substrate support member 152. Dynamic impedance matching from the RF power source matching box 143 may be provided when generating the capacitively coupled plasma (CCP).

In addition to the RF power source 147, a RF bias power source 145 may be coupled to the substrate support member 152. In one example, the RF bias power source 145 is configured to deliver an RF signal to an electrode 163 disposed with the substrate support member 152 at a frequency between 100 kHz and 120 MHz, such as between 100 KHz and 40 MHz. In at least one embodiment, the substrate support member 152 is configured as a cathode including an electrode 163 that is coupled to the RF bias power source 145. The RF bias power source 145 may be coupled between the electrode 163 disposed in the substrate support member 152 and another electrode, such as the showerhead 118 or ceiling such as top plate 114 of the chamber body 130. The RF bias power generated from the RF bias power source 145 excites and sustains a plasma discharge formed from the gases disposed in the interior processing region 151 of the chamber body 130. In some alternate embodiments, the RF bias power source 145 may be configured to provide pulsed voltage waveform at a frequency between 50 KHz and 500 kHz by use of pulsed DC voltage power supply.

In some embodiments, the substrate 301 is disposed on the substrate support member 152 in the deposition processing chamber 100. A process gas may be introduced into the chamber body 130 through the showerhead 118 from the gas sources 106. The vacuum pump 146 can maintain the pressure inside the chamber body 130 while removing deposition byproducts.

A controller 170 may be coupled to the deposition processing chamber 100 to control one or more operations of the deposition processing chamber 100. The controller 170 includes a central processing unit (CPU) 172, a memory 174, and a support circuit 176 utilized to control a process sequence and regulate gas flows from the gas sources 106. The CPU 172 may be any general purpose computer processor that may be used in an industrial setting. The software routines can be stored in the memory 174, such as random access memory, read only memory, floppy, or hard disk drive, or other form of digital storage. In at least one embodiment, the support circuit 176 is coupled to the CPU 172, and includes cache, clock circuits, input/output systems, power supplies, and the like. Bi-directional communications between the controller 170 and the various components of the deposition processing chamber 100 are handled through numerous signal cables.

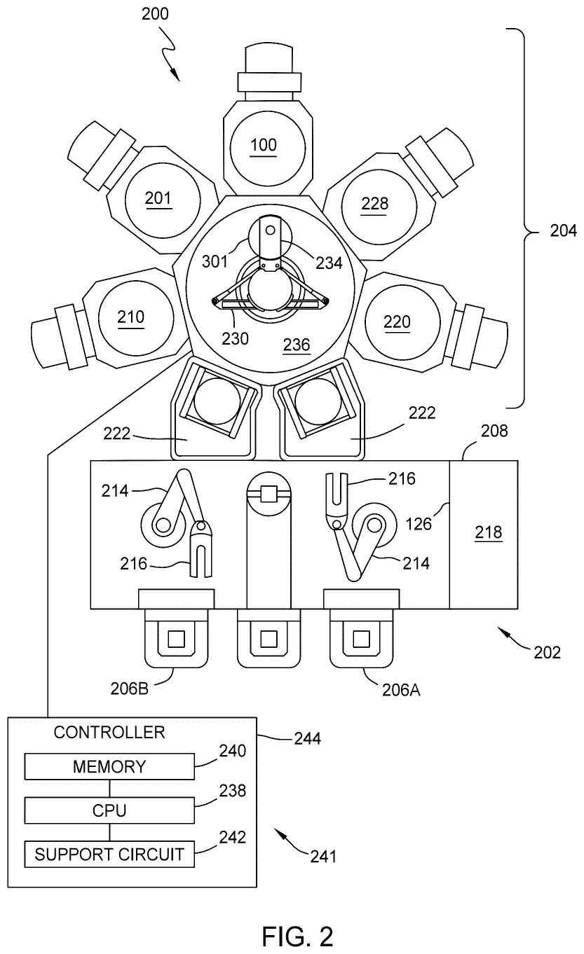

FIG. 2 is a schematic, top plan view of an exemplary processing system 200 that includes one or more processing chambers, such as the deposition chamber 100 illustrated in FIG. 1 that is incorporated and integrated therein. In some embodiments, the processing system 200 may be a CENTURA® integrated processing system, commercially available from Applied Materials, Inc., located in Santa Clara, Calif. It is contemplated that other processing systems (including those from other manufacturers) may be adapted to benefit from the disclosure.

The processing system 200 includes a vacuum-tight processing platform 204, a factory interface 202, and a system controller 244. The processing platform 204 includes at least one processing chamber 203, such as the deposition chamber 100 depicted from FIG. 1, a plurality of processing chambers 201, 228, 220, 210, and at least one load-lock chamber 222 that is coupled to a vacuum substrate transfer chamber 236. The factory interface 202 is coupled to the transfer chamber 236 by the load lock chambers 222.

In some embodiments, the factory interface 202 includes at least one docking station 208 and at least one factory interface robot 214 to facilitate transfer of substrates. The docking station 208 is configured to accept one or more front opening unified pod (FOUP). Two FOUPS 206A-B are shown in the embodiment of FIG. 2. The factory interface robot 214 has a blade 216 disposed on one end of the robot 214 and is configured to transfer the substrate from the factory interface 202 to the processing platform 204 through the load lock chambers 222.

In at least one embodiment, the one or more processing chambers 203, 201, 210, 220, 228 may be connected to a terminal 126 of the factory interface 202 to facilitate processing of the substrate from the FOUPS 206A-B.

In one or more embodiments, each of the load lock chambers 222 have a first port coupled to the factory interface 202 and a second port coupled to the transfer chamber 236. The load lock chambers 222 are coupled to a pressure control system (not shown) which pumps down and vents the load lock chambers 222 to facilitate passing the substrate between the vacuum environment of the transfer chamber 236 and the substantially ambient (e.g., atmospheric) environment of the factory interface 202.

The transfer chamber 236 may include a vacuum robot 230 disposed therein. The vacuum robot 230 can have a blade 234 capable of transferring substrates 301 among the load lock chambers 222, the deposition chamber 203, processing chamber 201, and the processing chambers 201, 210, 220, 228.

In one or more embodiments, the processing system 200 includes a processing chamber 203, such as the deposition chamber 100 depicted in FIG. 1, and other processing chambers 201, 210, 220, 228, which may be a deposition chamber, etch chamber, thermal processing chamber, curing chamber, or other similar type of semiconductor processing chamber that may assist forming a dielectric material with good gap filling capability to be filled in a trench in semiconductor devices.

The system controller 244 is coupled to the processing system 200. The system controller 244, which may include the computing device 241 or be included within the computing device 241, controls the operation of the processing system 200 using a direct control of the processing chambers 203, 201, 210, 220, 228 of the processing system 200. Alternatively, the system controller 244 may control the computers (or controllers) associated with the processing chambers 203, 201, 210, 220, 228 and the system 200. In operation, the system controller 244 also enables data collection and feedback from the respective chambers and the processing chambers 203 to optimize performance of the processing system 200.

The system controller 244, much like the controller 170 described above, generally includes a central processing unit (CPU) 238, a memory 240, and support circuits 242. The CPU 238 may be one of any form of a general purpose computer processor that can be used in an industrial setting. The support circuits 242 are conventionally coupled to the CPU 238 and may comprise cache, clock circuits, input/output subsystems, power supplies, and the like. The software routines transform the CPU 238 into a specific purpose computer (controller) 244. The software routines may also be stored and/or executed by a second controller (not shown) that is located remotely from the processing system 200. In some embodiments, the system controller 244 and the controller 170 are the same controller.

In some embodiments, as discussed above, the system 200 is an integrated system that includes: a vacuum substrate transfer chamber; a deposition chamber configured for flowable chemical vapor deposition coupled to the vacuum substrate transfer chamber; and a processing chamber coupled to the vacuum substrate transfer chamber, wherein the processing chamber is configured to cure a formed dielectric material (e.g., low-k material) using a plasma cure operation. In some embodiments, the processing chamber of the integrated system is configured to control the temperature of the dielectric material at a temperature of 0° C. to 500° C. during processing. In some embodiments, the processing chamber is configured to maintain the dielectric material at a pressure of 3 mTorr to 100 mTorr. In some embodiments, the processing chamber is configured to apply a bias power to the substrate on which the dielectric material is formed in an amount of 30 W to 5000 W. In some embodiments, the processing chamber is configured to provide 100 W to about 5000 W plasma power. In some embodiments, the processing chamber is configured to form a plasma using a process gas including a noble gas based plasma. In one or more embodiments, the processing chamber is configured to form a plasma using a process gas including one or more of helium (He), argon (Ar), hydrogen (H₂), ammonia (NH₃), disilane (Si₂H₆), methane (CH₄), acetylene (C₂H₂), nitrogen trifluoride (NF₃), tetrafluoromethane (CF₄), sulfur hexafluoride (SF₆), carbon monoxide (CO), trifluoromethane (CHF₃), chlorine (Cl₂), hydrogen bromide (HBr), nitrogen (N₂), oxygen (O₂), xenon (Xe), and combinations thereof. In some embodiments, the deposition chamber is configured to form a dielectric material at a temperature of about 0° C. to about 100° C. during processing. In some embodiments, the deposition chamber is configured to form a dielectric material at a pressure of 100 mTorr to 5 Torr. In some embodiments, the deposition chamber is configured to form a dielectric material while applying a bias power to the dielectric material in an amount of 30 W to 5000 W.

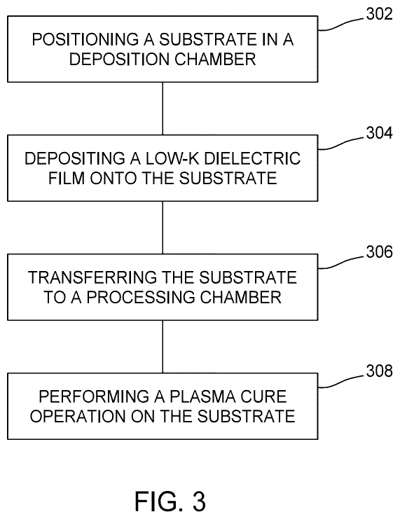

FIG. 3 shows a flowchart illustrating a method 300 of plasma curing a dielectric material, such as a material formed by a flowable CVD process. The method 300 includes a first operation 302, wherein a substrate is positioned within a deposition chamber, such as the deposition chamber 100 depicted in FIG. 1. The second operation 304 of the method 300 includes depositing a dielectric film onto the substrate. The third operation 306 includes transferring the substrate with the dielectric film deposited thereon from the deposition chamber to a processing chamber. In some embodiments, the processing chamber is similar to the deposition chamber 100 illustrated in FIG. 1, and generally includes a capacitively coupled (CCP) source assembly that includes the RF power source 147 that is configured to RF bias the showerhead 118. The substrate is then subjected to a plasma cure operation (e.g., operation 308) to increase the density and degree of crosslinking of the low-k dielectric film deposited thereon.

The first operation 302 of the method 300 includes positioning a substrate within a deposition chamber. The substrate will include a surface that has one or more structures, features, trenches and/or vias formed thereon. The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate may have various dimensions, such as 200 mm, 300 mm, 450 mm or other diameter wafers, as well as, rectangular or square panels. Unless otherwise noted, embodiments and examples described herein are conducted on substrates with a 200 mm diameter, a 300 mm diameter, or a 450 mm diameter substrate. In the embodiment wherein a SOI structure is utilized for the substrate, the substrate may include a buried dielectric layer disposed on a silicon crystalline substrate.

In some embodiments, the substrate includes a patterned surface having one or more openings that expose portions of an interface layer for depositing a dielectric material therein. The one or more openings described herein may include trenches, vias, openings and the like. In at least one embodiment, the patterned surface may comprise a material layer including a metal containing material, a silicon containing material, a carbon containing materials, and/or other suitable materials. Suitable examples of the metal containing materials include copper containing materials, aluminum containing materials, nickel containing materials, tungsten containing materials, or other metal containing materials. Suitable silicon containing materials include silicon, silicon oxide, silicon nitride, silicon oxynitride, and combinations thereof. Suitable carbon containing materials include silicon carbide, amorphous carbon or the like. In at least one embodiment, the patterned material layer is a silicon layer.

In some embodiments, the interface layer is a dielectric layer, such as a dielectric oxide layer or dielectric nitride layer. The interface layer may include multiple layers, composite layers, or a single layer. Other suitable materials for the dielectric layer include undoped silicon glass (USG), such as silicon oxide or TEOS, boron-silicate glass (BSG), phosphorus-silicate glass (PSG), boron-phosphorus-silicate glass (BPSG), silicon nitride, amorphous silicon, and combinations thereof.

At operation 304 of the method 300, a deposition gas mixture is supplied to the processing chamber, such as the processing chamber 100 in FIG. 1, to perform the deposition process to form a dielectric material in the one or more opening of the substrate surface (also referred to as a deposited substrate). The gas mixture supplied to the processing chamber may be varied based on different types of materials to be formed and filled in the one or more openings on the substrate surface. In at least one embodiment, the dielectric material to be formed is a silicon nitride layer. As such, the deposition gas mixture as supplied comprises at least one silicon containing gas, nitrogen containing gas, or optionally an inert gas. In at least one embodiment, the dielectric material to be formed is a silicon oxide layer. As such, the deposition gas mixture as supplied comprises at least one silicon containing gas, oxygen containing gas, or optionally an inert gas. In at least one embodiment, the dielectric material to be formed is a silicon carbide layer. As such, the deposition gas mixture as supplied comprises at least one silicon containing gas, carbon containing gas, or optionally an inert gas. In at least one embodiment, the dielectric material to be formed is a carbide layer. As such, the deposition gas mixture as supplied comprises at least one carbon containing gas, or optionally an inert gas. In some embodiments, the deposited dielectric material may include a low-k dielectric material that is selected from a group that consists of silicon oxide (SiO₂), silicon oxide nitride (SiON), silicon nitride (Si₃N₄), silicon oxide carbide (SiOC), silicon oxycarbonitride (SiOCN), or combinations thereof.

In some embodiments, the deposition gas mixture used supplied to the deposition chamber in operation 304 includes one or more of a silicon containing gas, a nitrogen containing gas, an oxygen containing gas, a carbon containing gas, an inert gas, and combinations thereof. In at least one embodiment, a silicon containing gas can include SiH₄, TEOS, Si₂H₆, and combinations thereof. In at least one embodiment, a nitrogen containing gas can include N₂, NH₃, N₂O, NO₂, and combinations thereof. In at least one embodiment, an oxygen containing gas can include H₂O₂, H₂O, O₂, O₃, and combinations thereof. In at least one embodiment, a carbon containing gas can include CO₂, hydrocarbon gases (e.g., CH₄ and C₂H₆), and combinations thereof. In at least one embodiment, an inert gas can include He, Ar, and combinations thereof. The deposition gas mixture may further include a carrier gas, such as N₂, H₂, and combinations thereof.

In at least one embodiment, the deposition gas mixture includes a silicon containing gas, a nitrogen containing gas, and an inert gas to deposit a silicon nitride layer as the dielectric material. In at least one embodiment, the deposition gas mixture includes a silicon containing gas, an oxygen containing gas, and an inert gas to deposit a silicon oxide layer as the dielectric material. In at least one embodiment, the deposition gas mixture includes a silicon containing gas, a carbon containing gas, and an inert gas to deposit a silicon carbide layer as the dielectric material.

In some embodiments, the silicon containing gas is introduced to the deposition chamber using a controlled flow rate between about 30 sccm and about 5000 sccm by volume, such as about 100 to about sccm to about 2500 sccm by volume, such as about 500 sccm to about 2000 sccm by volume, such as about 1000 sccm to about 1500 sccm by volume, alternatively about 100 sccm to about 500 sccm by volume, alternatively about 500 sccm to about 1000 sccm by volume, alternatively about 1000 sccm to about 1500 sccm by volume, alternatively about 1500 sccm to about 2000 sccm by volume, alternatively about 2000 sccm to about 2500 sccm by volume, alternatively about 2500 sccm to about 5000 sccm by volume. In some embodiments, the oxygen, carbon, or nitrogen containing gas is introduced to the deposition chamber using a controlled flow rate between about 5 sccm and about 2000 sccm by volume, such as about 100 sccm to about 1500 sccm by volume, such as about 500 sccm to about 1000 sccm by volume, alternatively about 50 sccm to about 100 sccm by volume, alternatively about 100 sccm to about 500 sccm by volume, alternatively about 1000 sccm to about 1500 sccm by volume, alternatively about 1500 sccm to about 2000 sccm by volume. In some embodiments, the inert gas is introduced to the deposition chamber using a controlled flow rate between about 250 sccm and about 6000 sccm by volume, such as about 500 sccm to about 3000 sccm by volume, such as about 1000 sccm to about 2000 sccm by volume, alternatively about 250 sccm to about 500 sccm by volume, alternatively about 500 sccm to about 1000 sccm by volume, alternatively about 2000 sccm to about 3000 sccm by volume, alternatively about 3000 sccm to about 6000 sccm by volume.

In some embodiments, gases from the deposition gas mixture may be supplied from the gas source 106 through the remote plasma source 104 to the interior processing region 151, while some of the gases may be supplied through a side of the deposition chamber 100, such as the fluid sources 119 that are laterally formed around the showerhead 118, to be delivered to the interior processing region 151. In some examples, a first gas (e.g., the reactive precursors) from the deposition gas mixture, such as silicon containing gases, are supplied from side (e.g., the fluid sources 119) of the deposition chamber 100 while a second gas (e.g., the carrier gas, inert gas, carbon or nitrogen containing gases or other gases) from the deposition gas mixture are supplied from the gas source 106 through the remote plasma source 104 to the interior processing region 151. In one example, the first gas is SiH₄ gas supplied from the fluid sources 119 into the processing chamber while the second gas is at least one of Ar, He, NH₃, H₂, N₂, or combinations thereof supplied from the gas source 106 through the remote plasma source 104 to the interior processing region 151.

After the deposition gas mixture is supplied to the processing chamber, a remote plasma source power is applied to the remote plasma source 104 to generate a remote plasma to be delivered from the remote plasma source 104 to the interior processing region 151. Without being bound by theory, remotely dissociated gas and/or other gases can provide high density and low energy atomic species, as compared to applying an RF source power applied to the showerhead, which may provide high energy but relatively low concentration of gas radicals. Thus, by utilizing the remote plasma source with certain active gas species along with the gases supplied from the side, e.g., from the fluid sources 119, the high density gas species with relatively low energy atomic species, are then delivered to the interior processing region 151 to form the dielectric material on the substrate. Without being bound by theory, atomic gas species from the remote plasma source has higher degree of reactivity, which may react with reacting gas precursors supplied from the side, e.g., from the fluid sources 119, more efficiently, slowly and thoroughly, thus providing a good gap filling capability to fill the dielectric material into the one or more openings on the substrate's surface.

It is noted that the amount of each gas introduced into the processing chamber may be varied and adjusted to accommodate, for example, the thickness of the dielectric material to be formed in the one or more openings of the substrate. In one or more embodiments, the gases supplied from the remote plasma source 104 may have certain ratios. For example, a ratio of the nitrogen containing gas to the Ar gas may be controlled between about 0.2:1 and about 2:1 by volume, such as about 0.5:1 to about 1.5:1 by volume, such as about 0.75:1 to about 1.25:1 by volume.

In one or more embodiments, a remote RF source power is supplied to the remote plasma source 104 to generate remote plasma to be delivered to the interior processing region 151. The frequency at which the power to the remote plasma source 104 is applied from about 50 kHz to about 2.45 GHz. A substrate temperature is maintained between about-20° C. to about 200° C., such as about 0° C. to about 100° C., such as about 25° C. to about 75° C.

While supplying the remote plasma from the remote plasma source 104 to the interior processing region 151, a pulsed RF bias power may be applied to the substrate support member 152 to generate a RF bias power to the substrate disposed on the substrate support member 152. It is noted that the RF bias power generated to the substrate support member 152 is utilized to assist providing directionality to the plasma in the interior processing region 151 during the deposition process. In one embodiment, the RF bias power may be provided at about 2 MHz to about 60 MHz as needed, such as about 13 MHz to about 40 MHz.

In some embodiments, the RF bias power may be supplied to the substrate support member 152 in pulsed mode. It is believed that the RF bias power supplied in a pulse mode can provide a relatively mild RF power level to the substrate disposed on the substrate support assembly so that the reactive species can be accelerated toward the substrate with a relatively mild energy level. The RF bias power supplied to the substrate support member 152 may be simultaneously, concurrently, separately, alternatively, or sequentially with the remote plasma power supplied from the remote plasma source 104.

In one particular embodiment, the RF bias power is provided at about 2MHz to about 60 MHz, such as about 13 MHz to about 40 MHz. In one example, a RF bias power is supplied at between about 100 W and about 2000 W to the substrate support member 152, such as about 500 W to about 1500 W, such as about 750 W to about 1250 W, alternatively about 100 W to about 500 W, alternatively about 500 W to about 750 W, alternatively about 750 W to about 1000 W, alternatively about 1000 W to about 1250 W, alternatively about 1250 W to about 1500 W, alternatively about 1500 W to about 2000 W. The RF bias power may be utilized at duration between about 100 μs to about 200 ms, such as about 500 μs to about 100 ms, such as about 1 ms to about 50 ms. A substrate temperature is maintained between about −20° C. to about 100° C., such as about 0° C. to about 75° C., such as about 25° C. to about 50° C.

At operation 306 of the method 300, the substrate is transferred from the deposition chamber to a processing chamber, such as a plasma processing chamber. The processing chamber may be any suitable processing chamber using plasma or plasma-assisted technology, such as the chamber 100 of FIG. 1. A suitable plasma processing chamber generates a plasma to bombard, densify, and cure the dielectric material layer with ions from the generated plasma.

The substrate is then subjected to a plasma cure operation (e.g., operation 308) to prepare a processed substrate. In some embodiments, the plasma cure operation of operation 308 is performed in an oxygen-containing ambient environment prepared by introducing one or more oxygen containing gases into the processing chamber. The one or more oxygen containing gases may include molecular oxygen (O₂), ozone (O₃), water vapor (H₂O), nitric oxide (NO), nitrogen dioxide (NO₂), nitrous oxide (N₂O), and combinations thereof. In some embodiments, the plasma cure operation of operation 308 is performed in a nitrogen-containing ambient environment prepared by introducing one or more nitrogen containing gases into the processing chamber. The one or more nitrogen containing gases may include nitrogen (N₂), ammonia (NH₃), and combinations thereof. In at least one embodiment, the gas introduced to the plasma processing chamber may include an inert gas, such as argon, hydrogen, or helium.

In some embodiments, the gas introduced to the plasma processing chamber during operation 308 includes a noble gas, such as xenon (Xe). The gas introduced to the plasma processing chamber during operation 308 may include a noble gas, such as Xe, and one or more reactive gases, such as O₂, N₂, H₂, or a combination thereof. Without being bound by theory, the presence of Xe and/or another noble gas in the formed plasma enable increased ion energy due to its higher atomic mass and the generation of a high intensity UV light emission at wavelengths between 200-900 nanometers (nm) compared to other gases allowing for increased cure depth from the surface of the dielectric material layer. It is believed that exposing the deposited FCVD film formed on the surface of the substrate to a spatially distributed plasma generated emission spectrum of a Xe and/or other noble gas containing plasma generated by a CCP plasma source assembly, versus a conventional spatially narrow noble gas lamp design, can be used to broadly and uniformly expose the deposited FCVD film so as to enhance the curing process results. Combinations of noble gases (e.g., Xe) and reactive gases, such as O₂, N₂, H₂, and combinations thereof, during a plasma cure operation can allow for compositional control of the dielectric material. That is to say that plasma cure processes disclosed herein (e.g., operation 308) allow for the formation of favorable bonds and/or increased crosslinking, which can result in superior film properties (e.g., high breakdown voltage, low leakage, lower k-value and higher downstream etch resistance). For instance, plasma cure processes disclosed herein have been shown to decrease the amount of Si—CH₃ bonds present in the deposited dielectric film, while also increasing the amount of Si—O therein. Such compositional changes can be modulated by adjusting one or more parameters of the plasma cure operation. Additionally, the compositional changes of the dielectric material layer resulting from plasma cure operations disclosed herein can lead to increased breakdown voltage and lowered k values. Furthermore, plasma cure operations disclosed herein can be performed at high pressure and high power regimes to enable increased cure depth (e.g., depth of cure relative to the surface of the dielectric material layer) without damaging the surface of the substrate

Without being bound by theory, the plasma treatment combines material conversion and densification in one operation without the need of a long duration thermal anneal process, which is typically performed after the curing process in the conventional formation of FCVD films to further incorporate oxygen or nitrogen atoms into the layer. In some embodiments, a high-density plasma can also be used to lower thermal budget as compared to thermal anneal. As a result, the overall thermal budget of a fabrication process is reduced.

During the plasma cure operation of operation 308, the temperature within the plasma processing chamber may be maintained at about 50° C. to about 200° C., such as about 75° C. to about 175° C., such as about 100° C. to about 150° C. In at least one embodiment, the pressure within the plasma processing chamber is maintained at about 1 mTorr to about 100 Torr, such as about 500 mTorr to about 50 Torr, such as about 1 Torr to about 10 Torr.

The plasma chamber implemented in operation 308 may be any suitable plasma chamber that has separate controls for power input to a plasma source generator and/or to a substrate bias device. The plasma chamber may include a plasma source controller (e.g., RF power source 147) to control the supply of RF power provided to the plasma source (e.g., CCP source), thus allowing for modulation of the source power, ion energy, and plasma density. The plasma chamber may also include a bias controller (e.g., RF bias power source 145) to control RF power or DC power, which is used to generate a bias voltage on the substrate surface. The bias voltage is used to attract ions from the plasm formed in the processing region to the substrate.

The bias voltage can be used to control the bombardment energy of the ion species on the substrate surface and/or more specifically the dielectric material layer. Source power and chamber pressure are variable by which plasma gas ionization may be controlled. Additionally and/or alternatively, bias power provides additional variable by which to modulate ion energy for film treatment depth control. Furthermore, using a low pressure can enables long mean-free path and deep trench layer treatment. One suitable plasma chamber is a Centura® Advantedge™ Mesa™ Etch chamber available from Applied Materials of Santa Clara, Calif.

In some embodiments, the plasma chamber used in operation 308 is configured to include a plasma source, such as a capacitively coupled plasma (CCP) source. However, in other embodiments, an inductively coupled plasma (ICP) source, a decoupled plasma (DCP) source, a magnetron plasma source, an electron cyclotron resonance (ECR) source, a microwave plasma source, or a combination thereof can be used. As discussed above, in at least one embodiment, the plasma chamber of operation 308 includes a CCP source that is configured to form a plasma over a surface of a substrate by delivering an RF signal to an electrode (e.g., showerhead 118) disposed within a processing region of a processing chamber. In at least one embodiment, a source power applied to the plasma source during operation 308 can be provided at an RF power level from about 100 W to about 5 KW, such as about 500 W to about 2.5 KW, such as about 1kW to about 2 KW. The source power may be applied at a radio frequency (RF) range of about 1 MHz to about 120 MHz, such as about 2 MHz to about 60 MHZ, such as about 10 MHz to about 25 MHz. In at least one embodiment, a bias power is provided to a substrate and/or a substrate support, wherein the bias power may be from about 100 W to about 2 KW, such as about 500 W to about 1.5 KW, such as about 1 kW to about 1.25 KW. The bias power may be applied at a RF range of about 2 MHz to about 40 MHz, such as about 13 MHz to about 40 MHz.

In some embodiments, the process gas delivered into the plasma processing chamber during operation 308 at a gas flow rate of about 5 sccm to about 10,000 sccm, such as about 50 sccm to about 1000 sccm, such as about 100 sccm to about 500 sccm. The first gas introduced into the plasma processing chamber can include one or more of O₂, O₃, H₂O, NO, NO₂, N₂O, N₂, NH₃, H₂, Xe, other noble gases, and combinations thereof. In at least one embodiment, the first process gas includes a mixture of a noble gas (e.g., Xe) and H₂, wherein the ratio of the noble gas to H₂ is from about 0.1:1 to about 1:0.1, such as about 0.5:1 to about 1:0.5, such as about 0.9:1 to about 1:0.9. In at least one embodiment, the noble gas (e.g., Xe) is flown into the plasma processing chamber during operation 308 at a gas flow rate of about 100 sccm to about 5000 sccm, such as about 500 sccm to about 2500 sccm, such as about 1000 sccm to about 2000 sccm. In at least one embodiment, H₂ is flown into the plasma processing chamber during operation 308 at a gas flow rate of about 100 sccm to about 5000 sccm, such as about 500 sccm to about 2500 sccm, such as about 1000 sccm to about 2000 sccm.

In some embodiments, the partial pressure of the noble gas (e.g., Xe) within the plasma processing chamber during operation 308 is about 100 mTorr to about 30 Torr, such as about 500 mTorr to about 15 Torr, such as about 1 Torr to about 10 Torr. In some embodiments, the partial pressure of H₂ within the plasma processing chamber during operation 308 is about 100 mTorr to about 30 Torr, such as about 500 m Torr to about 15 Torr, such as about 1 Torr to about 10 Torr.

In some embodiments, the plasma cure operation of operation 308 is applied to a substrate for about 10 s to about 1000 s, such as about 100 s to about 500 s, such as about 150 s to about 250 s.

Upon completion of the plasma cure operation of operation 308, the processed substrate may have a k-value of about 2 to about 5, such as about 2.5 to about 4.5, such as about 3 to about 4. In some embodiments, the processed substrate has a breakdown voltage of less than about 7 MV/cm at a current of 1×10⁻⁶A/cm².

In some embodiments, the plasma cure operation of operation 308 results in a processed substrate having a cure depth of about 600 Å to about 1000 Å, wherein the cure depth is characterized by the depth of bulk compositional change resulting from the cure operation relative to the surface of the dielectric material undergoing the plasma cure operation. In at least one embodiment, the processed substrate has a cure depth of about 600 Å to about 1000 Å, such as about 700 Å to about 900 Å, such as about 750 Å to about 850 Å. In at least one embodiment, the parameters of the plasma cure operation of operation 308 are optimized to produce a processed substrate having a maximized cure depth.

### EXAMPLES

### Example 1

### Dielectric Material Deposition

Substrates were positioned in a deposition chamber. Then to form a deposited dielectric layer a deposition gas was provided into a processing region of a process chamber, and an RF power was applied to an electrode within the processing region and a bias was applied to a bias electrode to deposit a dielectric material onto the surface of the substrate. The deposition chamber was maintained at a temperature of about 65° C. and a pressure of about 0.8 Torr throughout the deposition operation. The deposition gas introduced to the deposition chamber included a silicon precursor (e.g., trisilyl amine), Ar, and He. The silicon precursor was introduced to the deposition chamber at a gas flow rate of about 1000 sccm. Argon was introduced to the deposition chamber at a gas flow rate of about 4000 sccm. He was introduced to the to the deposition chamber at a gas flow rate of about 1000 sccm. Additionally, the substrate support within the deposition chamber included a substrate bias of about 13.56 MHz applied thereto.

### Example 2

### Plasma Gas Composition and Resulting Electrical Properties of Processed Substrates

Substrates that included a deposited dielectric layer were then exposed to a plasma cure operation wherein the plasma gas introduced to the processing chamber was varied in composition. In one instance, the process gas included H₂ which was introduced to the processing chamber at a gas flow rate of about 1600 sccm. In a second instance, the process gas included Xe which was introduced to the processing chamber at a gas flow rate of about 1600 sccm. In a third instance, the process gas included a mixture of Xe and H₂, wherein the Xe was introduced to the processing chamber at a gas flow rate of about 1600 sccm and the H₂ gas was introduced to the processing chamber at a gas flow rate of about 1600 sccm. In each instance, the processing chamber was maintained at a temperature of between about 65° C. and 450° C., such as between about 300° C. and 400° C., such as about 385° C. and a pressure of between about 1 Torr and 100 Torr, such as about 30 Torr during the plasma cure operation. The plasma was formed by applying a source power of about 1 kW to the plasma source at a frequency of about 13.56 MHz. Each of the plasma cure operation were conducted for about 360 seconds.

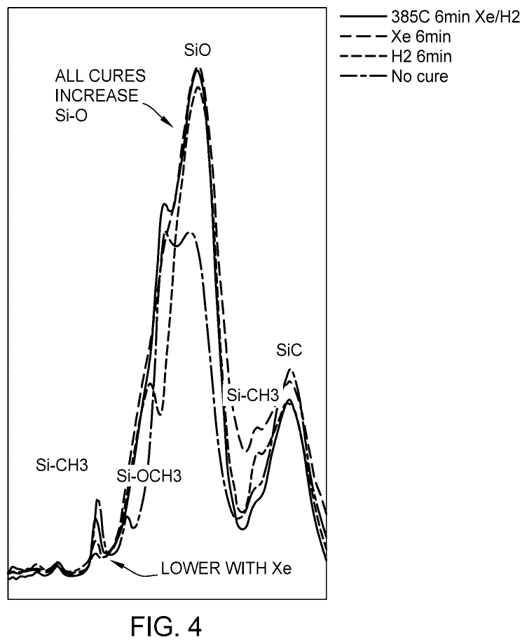

It was determined that each of the plasma gases (e.g., Xe, H₂, or Xe+H₂) implemented in the cure operations resulted in about a 10% reduction in the carbon content of the dielectric material layer when compared to the uncured species. To provide context, each of the samples were subjected to FTIR analysis (FIG. 4) to determine the compositions of the processed substrates. Such reductions in carbon content can be attributed to reductions in Si—CH₃ and Si—C bonds in the dielectric material layer of the processed substrate when compared to the uncured specimen, as evidenced by reductions in the Si—CH₃ and Si—C peaks shown in FIG. 4. Additionally, the FTIR spectra of FIG. 4 shows increases in the Si-O peaks for each of the cured samples when compared to the uncured samples. It was determined that each of the plasma gas compositions produce processed substrates having different electrical properties. It was determined that processed substrate formed using the Xe/H₂ plasma gas mixture exhibited carbon reduction, whilst also simultaneously increasing the voltage breakdown and lowering dielectric constant of the processed substrate.

### Example 3

### Temperature Effects on Resulting Electrical Properties of Processed Substrates

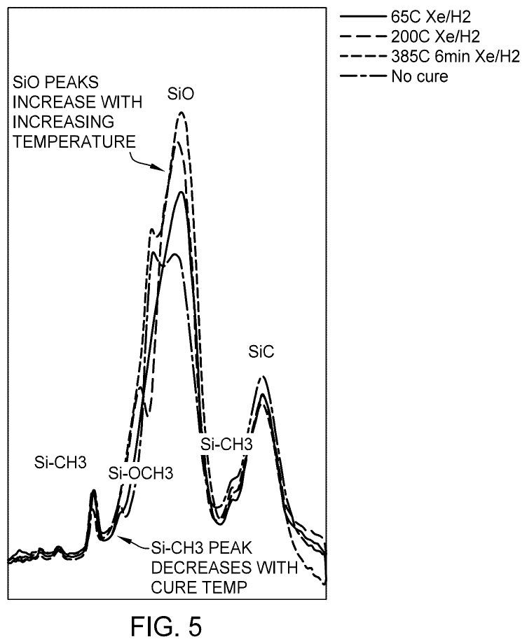

In another example, substrates underwent a plasma cure operation wherein the plasma gas introduced to the processing chamber included a mixture of Xe and H₂, wherein the Xe was introduced to the processing chamber at a gas flow rate of about 1600 sccm and the H₂ gas was introduced to the processing chamber at a gas flow rate of about 1600 sccm. In each instance, the processing chamber at a pressure of about 30 Torr during the plasma cure operation. The plasma was formed by applying a source power of about 1 kW to the plasma source at a frequency of about 13.56 MHz. The temperature during the plasma cure operation was varied from about 65° C. to about 385° C. Each of the plasma cure operation were conducted for about 10 min. FTIR spectra of the resulting compositions are shown in FIG. 5.

As determined via FTIR analysis (FIG. 5), it was found that increasing cure temperature of the plasma cure operation resulted in increased reduction in the carbon content of the processed substrate. The reduction in carbon content can be evidenced by the reductions of the Si—CH₃ and Si—C peaks increases of the Si—O peaks, as shown in FIG. 5. Additionally, it was found that increases in cure temperature of the plasma cure operation lead to increased voltage breakdown and lowered dielectric constants of the processed substrate.

### Comparison of Various Cure Operations

To establish and/or highlight the effectiveness of plasma cure processes disclosed herein, deposited substrates were subjected to various differing cure processes wherein the resulting processed substrates were evaluated based on their resulting electrical properties.

In this example, deposited substrates were formed by positioning a substrate into a deposition chamber, flowing a deposition gas into a process chamber, and applying a voltage to deposit a dielectric material onto the surface of the substrate. The deposition chamber was maintained at a temperature of about 65° C. and a pressure of about 0.8 Torr throughout the deposition operation. The deposition gas introduced to the deposition chamber included a silicon precursor, NH₃, H₂, Ar, and He. The silicon precursor was introduced to the deposition chamber at a gas flow rate of about 1000 sccm. NH₃ was introduced to the deposition chamber at a gas flow rate of about 550 sccm. H₂ was introduced to the deposition chamber at a gas flow rate of about 3000 sccm. Argon was introduced to the deposition chamber at a gas flow rate of about 4000 sccm. He was introduced to the to the deposition chamber at a gas flow rate of about 1000 sccm. Additionally, the substrate support within the deposition chamber included a pulsed bias of about 13 MHz applied thereto.

Each of the deposited substrates were then subjected to varying cure processes to produce processed substrates. In one instance, a processed substrate was cured via the plasma cure operation disclosed in Example 2, wherein the process gas composition included a mixture of Xe and H₂. Each of the Xe and H₂ where independently introduced to the processing chamber at a gas flow rate of about 1600 sccm. In a second instance, a processed substrate was thermally cured in a processing chamber wherein the processing chamber was maintained at a temperature of about 385° C. and a pressure of about 20 Torr. Additionally, Ar was introduced to the processing chamber at a gas flow rate of about 27,000 sccm. The thermal cure process was allowed to proceed for about 10 minutes. In a third instance, a processed substrate was prepared via a ultraviolet (UV) cure process wherein the processing chamber was maintained at a temperature of about 385° C. and a pressure of about 0 Torr. A process gas including NH3 and Ar were introduced to the processing chamber, each individually being flown into the processing chamber at a gas flow rate of about 5000 sccm. The specimen was then subjected to UV irradiation from about 10 min.

Each of the processed samples, cured via one of the above described cure operations, where then evaluated to determine the effect of a chosen cure process on the resulting electrical properties. The results from the electrical property analysis are summarized in Table 1.

TABLE 1
Summary of resulting electrical properties
as a function of cure process

| Cure Process | Voltage Breakdown | Dielectric Constant |
|---|---|---|
| None | 0.9 | 4.8 |
| Thermal Cure | 1.9 | 4.4 |
| UV Cure | 3 | 4.6 |
| Xe/H₂ Plasma Cure | 4 | 3.57 |

As evidenced from the electrical properties provided in Table 1, processed substrates prepared using plasma cure processes of the present disclosure exhibit improved breakdown voltage and lowered dielectric constant values than those prepared from traditional/conventional (e.g., UV cure and thermal cure) processes. Without being bound by theory, such electrical property improvements can be attributed to reductions in Si—CH₃ and Si—C bonds in the dielectric material layer of the processed substrate resulting from the plasma cure processes disclosed herein.

The present disclosure relates the plasma cure processes of a dielectric material layer disposed onto a substrate, such as dielectric materials disposed via a FCVD process. The plasma cure processes disclosed herein incorporate the use of a Xe based plasma gas to promote curing of the dielectric material layer. Substrate produced from plasma cure processes as described herein, which incorporate the use of a Xe based plasma gas, exhibit improved electrical properties over substrate cured using traditional/conventional cure processes. Such electrical property improvements can be attributed to reductions in Si—CH₃ and Si—C bonds and increases in Si—O bonds within the dielectric material layer. Such compositional changes are indicative of increased crosslinking of the dielectric material layer. Thus, plasma cure processes disclosed herein allow for new process regimes that enable increased plasma density in the processing chamber to modulate film composition. The ability to modulate film composition in a reliable manner allows for the formation of strong favorable networks from weaker starting structures.

While the foregoing is directed to embodiments of the present disclosure, other and further embodiments of the disclosure may be devised without departing from the basic scope thereof, and the scope thereof is determined by the claims that follow.

We claim:

1. A method of curing a substrate, the method comprising:
depositing a dielectric film onto a substrate to form a dielectric layer on a surface of a substrate; and
performing a plasma cure operation on the formed dielectric layer formed on the substrate, the plasma cure operation comprising:
generating a plasma over a surface of the formed dielectric layer by delivering a RF power to a plasma process gas, wherein the plasma process gas comprises a noble gas and H₂.

2. The method of claim 1, wherein the plasma process gas comprises a ratio of noble gas to H₂ of about 0.1:1 to about 1:0.1.

3. The method of claim 1, wherein the plasma cure operation further comprises delivering noble gas at a gas flow rate of about 100 sccm to about 5000 sccm within a processing region of a processing chamber in which the substrate is disposed, wherein the noble gas comprises Xe.

4. The method of claim 3, wherein the plasma process gas within the processing chamber comprises Xe at a partial pressure of about 100 mTorr to about 30 Torr.

5. The method of claim 3, wherein H₂ is introduced to the chamber at a gas flow rate of about 100 sccm to about 5000 sccm.

6. The method of claim 3, wherein the plasma process gas within the processing chamber comprises H₂ at a partial pressure of about 100 mTorr to about 30 Torr.

7. A method of curing a substrate, the method comprising:
positioning a substrate onto a substrate support within a processing chamber, the substrate comprising an uncured dielectric material disposed thereon; and
performing a plasma cure operation on the substrate, the plasma cure operation comprising:
generating a plasma over a surface of a dielectric layer by delivering a RF power supplied from a first RF source to a plasma process gas, wherein the plasma process gas comprises a noble gas and H₂ at a ratio of about 0.1:1 to about 1:0.1, and
applying a RF bias to the substrate support, wherein the RF bias is provided from a second RF source.

8. The method of claim 7, wherein the processing chamber comprises a partial pressure of the noble gas of about 100 mTorr to about 30 Torr, wherein the noble gas comprises Xe.

9. The method of claim 7, wherein the processing chamber comprises a partial pressure of H₂ of about 100 mTorr to about 30 Torr.

10. The method of claim 7, wherein the processing chamber is maintained at a temperature of about 50° C. to about 200° C.

11. The method of claim 7, wherein the processing chamber is maintained at a pressure of about 1 mTorr to about 100 Torr.

12. The method of claim 7, wherein the first RF power source is coupled to a showerhead and is configured to deliver RF power at about 100 W to about 5 kW.

13. The method of claim 12, wherein the RF bias is coupled to an electrode disposed within the substrate support and is configured to deliver RF power at about 100 W to about 2 kW.

14. The method of claim 13, wherein the RF bias is applied to the substrate support at a frequency of about 2 MHz to about 40 MHz.

15. A method of forming a cured substrate, the method comprising:
positioning a substrate onto a substrate support within a processing chamber, the substrate comprising an uncured dielectric material disposed thereon; and
performing a plasma cure operation on the substrate to form a cured substrate, wherein:
the plasma cure operation comprises introducing a plasma process gas having a noble gas and H₂ to the processing chamber, and applying an RF power to the plasma process gas to generate a plasma within the plasma processing chamber, and
the plasma cure operation causes a cured dielectric material to be formed on the substrate comprising a cure depth of about 600 Å to about 1000 Å.

16. The method of claim 15, wherein the cured dielectric material further comprises a dielectric constant of about 2 to about 5.

17. The method of claim 15, wherein the cured dielectric material further comprises a breakdown voltage of less than about 7 MV/cm at a current of 1×10⁻⁶ A/cm².

18. The method of claim 15, wherein the plasma is a capacitively coupled plasma (CCP).

19. The method of claim 18, wherein the plasma cure operation is performed for about 10 s to about 1000 s.

20. The method of claim 19, wherein plasma process gas is introduced to the processing chamber at a gas flow rate of about 5 sccm to about 10,000 sccm.
